(19) United States
(12) Patent Application Publication
(10) Pub. No.: US 2005/0116360 A1
(43) Pub. Date: Jun. 2, 2005

(54) Complementary field-effect transistors and methods of manufacture

(76) Inventors: Chien-Chao Huang, Hsin-Chu (TW); Fu-Liang Yang, Hsin-Chu (TW); Mickey Ken, Hsin-Chu (TW); Chenming Hu, Hsin-Chu (TW); Chung-Hu Ge, Taipei (TW); Wen-Chin Lee, Hsin-Chu (TW); Chih-Hsin Ko, Kaohsiung (TW)

Correspondence Address: SLATER & MATSIL, L.L.P., 17950 PRESTON ROAD, SUITE 1000, DALLAS, TX, 75252, US

(21) Appl. No.: 10/896,270

(22) Filed: Jul. 21, 2004

Related U.S. Application Data
(60) Provisional application No. 60/526,133, filed on Dec. 1, 2003.

(51) Int. Cl. H01L 31/0328

(52) U.S. Cl. 257/900

(57) ABSTRACT

A complementary FET and a method of manufacture is provided. The complementary FET utilizes a substrate having a surface layer with a <100> crystal orientation. Tensile stress, which increases performance of the NMOS FETs, is added by silicided source/drain regions, tensile-stress film, shallow trench isolations, inter-layer dielectric, or the like.

This application claims the benefit of U.S. Provisional Application No. 60/526,133 filed on Dec. 1, 2003, entitled Complementary Field-Effect Transistors and Method of Manufacture, which application is hereby incorporated herein by reference.

### TECHNICAL FIELD

The present invention relates generally to semiconductor devices, and more particularly, to complementary field-effect transistors and methods of manufacture.

### BACKGROUND

Size reduction of metal-oxide-semiconductor field-effect transistors (MOSFET), including reduction of the gate length and gate oxide thickness, has enabled the continued improvement in speed, performance, density, and cost per unit function of integrated circuits over the past few decades. To further enhance transistor performance, strain may be introduced in the transistor channel for improving carrier mobilities. Generally, it is desirable to induce a tensile strain in the n-channel of an NMOS transistor in the source-to-drain direction, and to induce a compressive strain in the p-channel of a PMOS transistor in the source-to-drain direction. There are several existing approaches of introducing strain in the transistor channel region.

In one conventional approach, as described in a paper by J. Welser et al., entitled “NMOS and PMOS Transistors Fabricated in Strained Silicon/Relaxed Silicon-Germanium Structures,” published at the December 1992 International Electron Devices Meeting held in San Francisco, Calif., pp. 1000-1002 and incorporated herein by reference, a relaxed silicon germanium (SiGe) buffer layer is provided beneath the channel region. The relaxed SiGe layer has a larger lattice constant compared to relaxed Si, and the layer of Si grown on the relaxed SiGe will have its lattice stretched in the lateral direction, i.e., it will be under biaxial tensile strain. Therefore, a transistor formed on the epitaxial strained silicon layer will have a channel region that is under biaxial tensile strain. In this approach, the relaxed SiGe buffer layer can be thought of as a stressor that introduces strain in the channel region. The stressor, in this case, is placed below the transistor channel region.

This approach is very expensive because a SiGe buffer layer with thickness in the order of micrometers has to be grown. Numerous dislocations in the relaxed SiGe buffer layer exist and some of these dislocations propagate to the strained silicon layer, resulting in a substrate with high-defect density. Thus, this approach has limitations that are related to cost and fundamental material properties.

In another approach, strain in the channel is introduced after the transistor is formed. In this approach, a high stress film is formed over a completed transistor structure formed in a silicon substrate. The high stress film or stressor exerts significant influence on the channel, modifying the silicon lattice spacing in the channel region, and thus introducing strain in the channel region. In this case, the stressor is placed above the completed transistor structure. This scheme is described in detail in a paper by A. Shimizu et al., entitled “Local mechanical stress control (LMC): a new technique for CMOS performance enhancement,” published in pp. 433-436 of the Digest of Technical Papers of the 2001 International Electron Device Meeting, which is incorporated herein by reference.

The strain contributed by the high-stress film is believed to be uniaxial in nature with a direction parallel to the source-to-drain direction. However, uniaxial tensile strain degrades the hole mobility while uniaxial compressive strain degrades the electron mobility. Ion implantation of germanium can be used to selectively relax the strain so that the hole or electron mobility is not degraded, but this is difficult to implement due to the close proximity of the n-channel and p-channel transistors. Therefore, there is a need for an efficient and cost-effective method to induce strain such that the performance characteristics of transistors are enhanced.

### SUMMARY OF THE INVENTION

These and other problems are generally reduced, solved or circumvented, and technical advantages are generally achieved, by embodiments of the present invention, which provides a strained semiconductor device to improve the operating characteristics of the semiconductor device and a method of manufacture.

In one embodiment of the present invention, a semiconductor device is provided on a substrate wherein the current flow is substantially along the <100> crystal orientation of the substrate. A silicide region is formed substantially along the surface of the substrate beneath the spacers.

In another embodiment of the present invention, a semiconductor device is provided having a first transistor and a second transistor such that the current flow is substantially along a <100> crystal orientation of the substrate. The spacers of the first transistor are larger than the spacers of the second transistor. At least a portion of at least one of the spacers of the first transistor and the spacers of the second transistor is formed over a silicided region.

In still yet another embodiment of the present invention, a method is provided to form a semiconductor device. The method includes the steps of providing a substrate, forming on the substrate a transistor having spacers along the side of a gate electrode, and forming a silicided region substantially along the surface of the substrate such that at least a portion of the silicided region extends beneath the spacers. The transistor is formed such that current flow through the source/drain region of the transistor is substantially along the <100> crystal orientation of the substrate.

In yet another embodiment of the present invention, a method is provided to form a semiconductor device having a first transistor and a second transistor. The method includes the steps of providing a substrate, forming on the substrate a first transistor having a spacer formed along the side of a first gate electrode such that current flow through a source/drain region of the transistor is substantially along the <100> crystal orientation of the substrate; forming on the substrate a second transistor having a second spacers formed along the side of a second gate electrode, the second spacer being smaller than the first spacer, and forming a silicided region substantially along the surface of the substrate such that at least a portion of the silicided region extends beneath at least one of the first spacer and the second spacer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a-1e are cross-section views of a wafer after various process steps in accordance with one embodiment of the present invention;

FIG. 2 illustrates a wafer in accordance with one embodiment of the present invention; and

FIGS. 3a-3d illustrate structures of a semiconductor die of a wafer in accordance with one embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

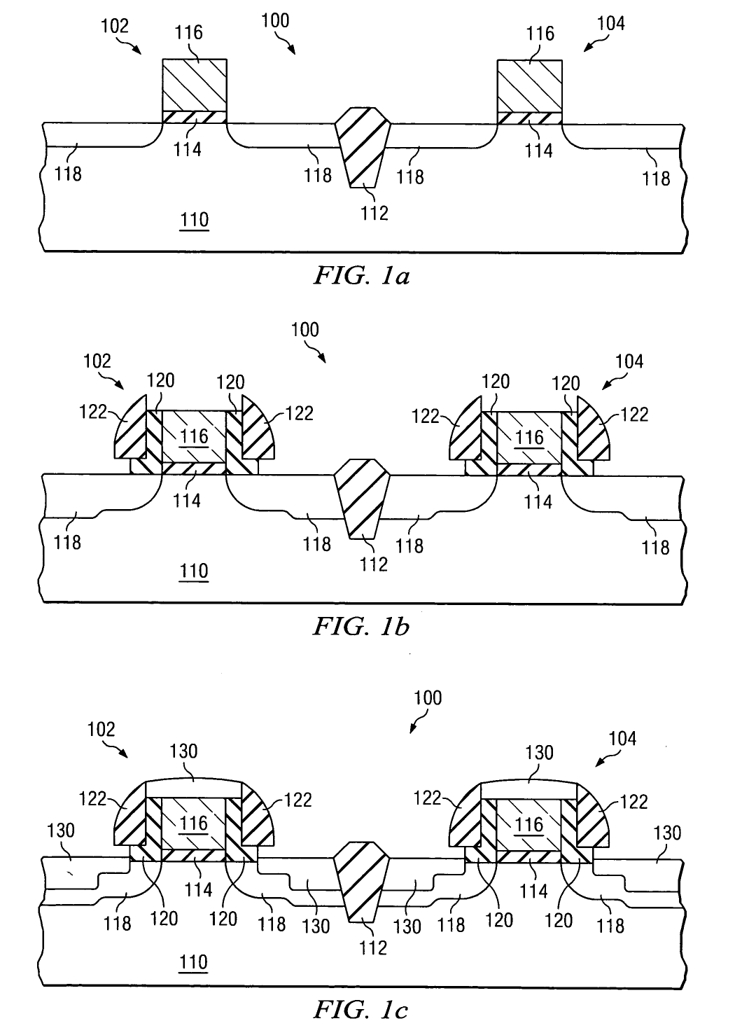

FIGS. 1a-1e illustrate a first method embodiment for fabricating strained channel regions of transistors in a semiconductor chip. Embodiments of the present invention illustrated herein may be used in a variety of circuits. For example, embodiments of the present invention may be utilized to form circuits for NOR gates, logic gates, inverters, XOR gates, NAND gates, PMOS transistors for pull-up transistor, NMOS transistor for pull-down transistor, and the like.

Referring first to FIG. 1a, a wafer 100 is shown comprising a first transistor 102 and a second transistor 104 formed on a substrate 110. In the preferred embodiment, the substrate 110 comprises bulk silicon having a crystal orientation of <100>. Alternatively, the silicon substrate 110 may be an active layer of a semiconductor-on-insulator (SOI) substrate. In this alternative embodiment, the active layer of the SOI comprises silicon having a crystal orientation of <100> formed on an insulator layer. The insulator layer may be, for example, a buried oxide (BOX) layer or a silicon oxide layer. The insulator layer is provided on a substrate, typically a silicon or glass substrate, but preferably a silicon substrate having a crystal orientation of <110>.

In another embodiment, the substrate 110 is a multi-layered structure, wherein the layers have different natural lattice constants. One such type of substrate is a graded silicon-germanium (SiGe) substrate with a strained silicon surface layer. Generally, a graded SiGe layer is formed on a bulk silicon layer, and a relaxed SiGe layer overlies the graded SiGe layer. The relaxed Si₁₋ₓGeₓ layer, wherein x is preferably 0.1<x<0.5 has a larger natural lattice constant than that of silicon. Relaxed crystalline silicon is said to be lattice-mismatched with respect to relaxed crystalline SiGe due to the difference in their lattice constants. As a result, a thin layer of silicon that is epitaxially grown on the relaxed SiGe layer will be under biaxial tensile strain because the lattice of the thin layer of silicon is forced to align to the lattice of the relaxed crystalline SiGe layer. In this embodiment, it is preferred that the strained silicon has a crystal orientation of <100>.

Another multi-layered substrate comprises a first layer having a first natural lattice constant. A second layer having a second natural lattice constant is formed on the first layer. The first layer may be formed of an alloy semiconductor, an element semiconductor, a compound semiconductor, or the like. For example, the first layer may be formed of SiGe, and the second layer may be formed of Si or a layer containing Ge/C. In these multi-layered substrates, the surface roughness of the strained surface layer is less than about 1 nm.

Isolation regions, such as shallow trench isolations 112, may be formed in the substrate 110. The STIs 112 are known and used in the art. It is understood that other isolation structures, such as field oxide (e.g., formed by the local oxidation of silicon) may be used. It should also be noted that the STI 112 may induce a tensile stress on the wafer 100.

A gate dielectric layer 114 and a gate electrode 116 are formed and patterned as is known in the art on the substrate 110. The gate dielectric 114 is preferably a high-K dielectric material, such as silicon oxide, silicon oxynitride, silicon nitride, an oxide, a nitrogen-containing oxide, a combination thereof, or the like. Preferably, the gate dielectric 114 has a relative permittivity value greater than about 4. Other examples of such materials include aluminum oxide, lanthanum oxide, hafnium oxide, zirconium oxide, hafnium oxynitride, or combinations thereof.

In the preferred embodiment in which the gate dielectric layer 114 comprises an oxide layer, the gate dielectric layer 114 may be formed by any oxidation process, such as wet or dry thermal oxidation in an ambient comprising an oxide, H₂O, NO, or a combination thereof, or by chemical vapor deposition (CVD) techniques using is tetra-ethyl-ortho-silicate (TEOS) and oxygen as a precursor. In the preferred embodiment, the gate dielectric layer 114 is about 8 Å to about 50 Å in thickness, but more preferably about 16 Å in thickness.

The gate electrode 116 preferably comprises a conductive material, such as a metal (e.g., tantalum, titanium, molybdenum, tungsten, platinum, aluminum, hafnium, ruthenium), a metal silicide (e.g., titanium silicide, cobalt silicide, nickel silicide, tantalum silicide), a metal nitride (e.g., titanium nitride, tantalum nitride), doped poly-crystalline silicon, other conductive materials, or a combination thereof. In one example, amorphous silicon is deposited and recrystallized to create poly-crystalline silicon (poly-silicon). In the preferred embodiment in which the gate electrode is poly-silicon, the gate electrode 116 may be formed by depositing doped or undoped poly-silicon by low-pressure chemical vapor deposition (LPCVD) to a thickness in the range of about 400 Å to about 2500 Å, but more preferably about 1500 Å.

The gate dielectric 114 and the gate electrode 116 may be patterned by photolithography techniques as is known in the art. Generally, photolithography involves depositing a photoresist material, which is then masked, exposed, and developed. After the photoresist mask is patterned, an etching process may be performed to remove unwanted portions of the gate dielectric material and the gate electrode material to form the gate dielectric 114 and the gate electrode 116 as illustrated in FIG. 1a. In the preferred embodiment in which the gate electrode material is poly-crystalline silicon and the gate dielectric material is an oxide, the etching process may be a wet or dry, anisotropic or isotropic, etch process, but preferably is an anisotropic dry etch process.

In one embodiment, the width of the gate electrode is different for PMOS devices and NMOS devices. In one such embodiment, the ratio of the gate width of the PMOS devices to the gate width of the NMOS devices is about equal to the ratio of electron mobility to hole mobility in bulk silicon or strained silicon. In another embodiment, the ratio of the gate width of the PMOS devices to the gate width of the NMOS devices is about equal to the square root of the ratio of electron mobility to hole mobility in bulk silicon or strained silicon.

Source/drain regions 118 are a lightly-doped drain (LDD) formed by ion implantation. The source/drain regions 118 may be implanted with an n-type dopant, such as phosphorous, nitrogen, arsenic, antimony, or the like, to fabricate NMOS devices or may be implanted with a p-type dopant, such as boron, aluminum, indium, and the like, to fabricate PMOS devices. Optionally, NMOS devices may be fabricated on the same chip as PMOS devices. In this optional embodiment, it may be necessary to utilize multiple masking and ion implant steps as is known in the art such that only specific areas are implanted with n-type and/or p-type ions.

Optionally, an epitaxial silicon may be grown in the source/drain regions 118. For example, an epitaxial silicon layer about 200 Å may be grown on the wafer. In this situation, the LDD is preferably less than 200 Å above the surface of the substrate to 50 Å below the surface of the substrate.

It has also been found that orienting the transistors, or other semiconductor devices, such that the current flow will be substantially along the <100> crystal orientation of the substrate improves the hole and electron mobility. Accordingly, it is preferred that the masks used to pattern the source/drain regions 118 are such that the current flow through the source/drain regions 118 is substantially along the <100> crystal orientation of the substrate.

Referring now to FIG. 1b, a dielectric liner 120 and a spacer 122 have been formed on the sides of the gate electrode 116, and a second ion implant has been performed in the source/drain regions 118. Preferably, the dielectric liner 120 is one or more layers of an oxide formed by any oxidation process, such as wet or dry thermal oxidation in an ambient comprising an oxide, H₂O, NO, or a combination thereof, or by chemical vapor deposition (CVD) techniques using is tetra-ethyl-ortho-silicate (TEOS) and oxygen as a precursor. In the preferred embodiment, the dielectric liner is about 20 Å to about 350 Å in thickness, but more preferably about 150 Å in thickness.

The spacer 122, which forms a spacer for the second ion implant, preferably comprises silicon nitride (Si₃N₄), or a nitrogen containing layer other than Si₃N₄, such as SiₓN_{y}, silicon oxynitride SiOₓN_{y}, silicon oxime SiOₓN_{y}:H_{z}, or a combination thereof. In a preferred embodiment, the spacer 122 is formed from a layer comprising Si₃N₄ that has been formed using chemical vapor deposition (CVD) techniques using silane and ammonia as precursor gases.

In the preferred embodiment, the ratio of the width of the spacer 122 to the thickness of the dielectric liner 120 is less than 5, and more preferably, less than 3. Furthermore, it should noted that the width of the spacer may vary with the type of device. For example, it has been found that I/O devices may benefit from a larger spacer due to the amount of current the device is expected to handle. PMOS devices may also benefit from larger spacers. In particular, it has been found that larger spacers on PMOS devices help reduce tensile stress on the p-channel. In this example, it is preferred that the larger spacers are at least about 10% larger than the smaller spacers. To fabricate spacers of varying widths, it may be necessary to incorporate additional masking, deposition, and etching steps.

The spacer 122 may be patterned by performing an isotropic or anisotropic etch process. The preferred isotropic etch process uses a solution of phosphoric acid (H₃PO₄) wherein the dielectric liner 120 acts an etch stop. Because the thickness of the layer of Si₃N₄ is greater in the regions adjacent to the gate electrode 116, the isotropic etch removes the Si₃N₄ material on top of the gate electrode 116 and the areas of substrate 110 not immediately adjacent to the gate electrode 116, leaving the spacer 122 as illustrated in FIG. 1b. Preferably, the width of the spacer 122 varies as the gate length of the transistors 102 and 104 varies. In the preferred embodiment, the ratio of the width of the spacer 122 to the length of the gate electrode 116 is about 0.8 to about 1.5.

The dielectric liner 120 may be patterned, for example, by performing an isotropic wet etch process using a solution of hydrofluoric acid. Another etchant that may be used is a mixture of concentrated sulphuric acid and hydrogen peroxide, commonly referred to as piranha solution. A phosphoric acid solution of phosphoric acid (H₃PO₄) and water (H₂O) may also be used to pattern the dielectric liner 120.

It should be noted that it is desirable to etch a portion of the dielectric liner 120 from beneath the spacer 122 as illustrated in FIG. 1b. In the preferred embodiment, amount of recess is about 10% to about 70% of the width of the spacer 122, but more preferably about 30% of the width of the spacer.

It should also be noted that the etching process to create the recess may also remove a portion of the dielectric liner 120 and the gate electrode 116 along the top of the transistors 102 and 104. If desired, a mask may be applied to the top of the transistors 102 and 104 to prevent a recess in the top of the transistors 102 and 104.

After forming the spacers 122, a second ion implant may be performed in the source/drain regions 118 as is known in the art. The source/drain regions 118 may be implanted with an n-type dopant, such as phosphorous, nitrogen, arsenic, antimony, or the like, to fabricate NMOS devices or may be implanted with a p-type dopant, such as boron, aluminum, indium, or the like, to fabricate PMOS devices. Optionally, NMOS devices and PMOS devices may be fabricated on the same chip. In this optional embodiment, it may be necessary to utilize multiple masking and ion implant steps such that only specific areas are implanted with n-type and/or p-type ions. Furthermore, additional ion implants may be performed to create differing graded junction configurations.

Referring now to FIG. 1c, a silicidation process has been performed to create silicide areas 130. Generally, a silicidation process involves depositing a metal layer, such as, for example, nickel, cobalt, palladium, platinum, copper, molybdenum, titanium, tantalum, tungsten, erbium, zirconium, a combination thereof, or the like, and causing the metal layer to react with the silicon, thereby creating a silicide. In the preferred embodiment, the silicidation process utilizes a metal comprising nickel, cobalt, platinum, palladium, a combination thereof, or the like. The metal layer may be formed, for example, by conventional deposition techniques such as, for example, evaporation, sputter deposition, chemical vapor deposition (CVD), or the like.

Prior to depositing the metal layer, it is preferred to clean the wafer to remove native oxide. Cleaning solutions that may be used includes hydrofluoric acid, sulphuric acid, hydrogen peroxide, NH₄OH solution, a combination thereof, or the like.

The silicidation process may be performed by annealing, causing the metal layer to selectively react with exposed silicon regions (e.g., the source/drain regions 118) and the poly-semiconductor regions (e.g., the gate electrodes 116) to form a silicide. In the preferred embodiment in which the metal layer comprises nickel, platinum, palladium, or cobalt, the silicidation process forms nickel silicide, platinum silicide, palladium silicide, or cobalt silicide, respectively. The excess material of the metal layer may be removed, for example, by performing a wet dip in a solution of sulfuric acid, HCl, H₂O₂, hydrogen peroxide, NH₄OH, H₃PO₄ or the like.

It should be noted that the silicided portion of the silicon extends beneath the spacer 122 due to silicide cap layer thickness or the recess etched into the dielectric liner 120. It has been found that the silicide formed in this manner increases the tensile stress in the channel area of the transistors 102 and 104. As noted above, the tensile stress can enhance the flow of current in the channel area of the transistors, particularly with NMOS transistors.

In an alternative embodiment, one or more of the steps of etching the recess in the dielectric liner 120 and performing the silicidation process are only performed on NMOS devices, thereby enhancing the electron mobility while not affecting the hole mobility of the PMOS devices. In these alternative embodiments, it may be necessary to form a mask over the PMOS devices while performing one or both of these process steps.

Referring now to FIG. 1d, a tensile-stress film 140 is deposited over the transistors 102 and 104 to create a tensile stress substantially along the <100> direction. The tensile-stress film 140 may be silicon nitride or any other tensile-stress material and may be formed, for example, by a chemical vapor deposition (CVD) process. The CVD process can be a low-pressure CVD (LPCVD) process, a Rapid Thermal CVD (RTCVD), atomic layer CVD (ALCVD) or a plasma-enhanced CVD (PECVD) process, as commonly known and used in the art. Preferably, tensile-stress film exerts a tensile stress in the range of about 50 MPa to about 2.0 GPa substantially along the source-to-drain direction. It is also preferred that the thickness of the tensile-stress film is such that the ratio of the thickness of the tensile-stress film to the width of the spacer is about 0.5 to about 1.6. In one embodiment, however, the tensile-stress film comprises silicon nitride deposited by LPCVD having a magnitude of about 1.2 GPa, and in another embodiment, the tensile-stress film comprises silicon nitride deposited by PECVD having a magnitude of about 0.7 GPa.

In another embodiment, PMOS devices may have a compressive-stress film, or no stress film, while NMOS devices have a tensile-stress film. The compressive-stress film results in a compressive strain in the channel region of the p-channel devices in the source-to-drain direction to enhance hole mobility. The process of forming a compressive-stress film on PMOS devices and tensile-stress film on NMOS devices is further described below with reference to co-pending patent application Ser. No. 10/639,170, filed Aug. 12, 2003, entitled, “Strained Channel Complementary Field-Effect Transistors and Methods of Manufacture,” which is incorporated herein by reference.

Referring now to FIG. 1e, an inter-layer dielectric (ILD) 150 is deposited over the wafer 100. The ILD layer 150 typically has a planarized surface and may be comprised of silicon oxide formed by deposition techniques such as CVD. The ILD 150 is preferably about 1500 Å to about 8000 Å in thickness, but more preferably about 3000 Å to about 4000 Å in thickness. Furthermore, in one preferred embodiment, the ILD 150 exerts a tensile stress substantially along the <100> direction with a magnitude of about 0.1 GPa to about 2 GPa.

Thereafter, standard processing techniques may be used to complete fabrication of the semiconductor device, including process steps such as forming metal lines and layers, forming vias and plugs, packaging, and the like.

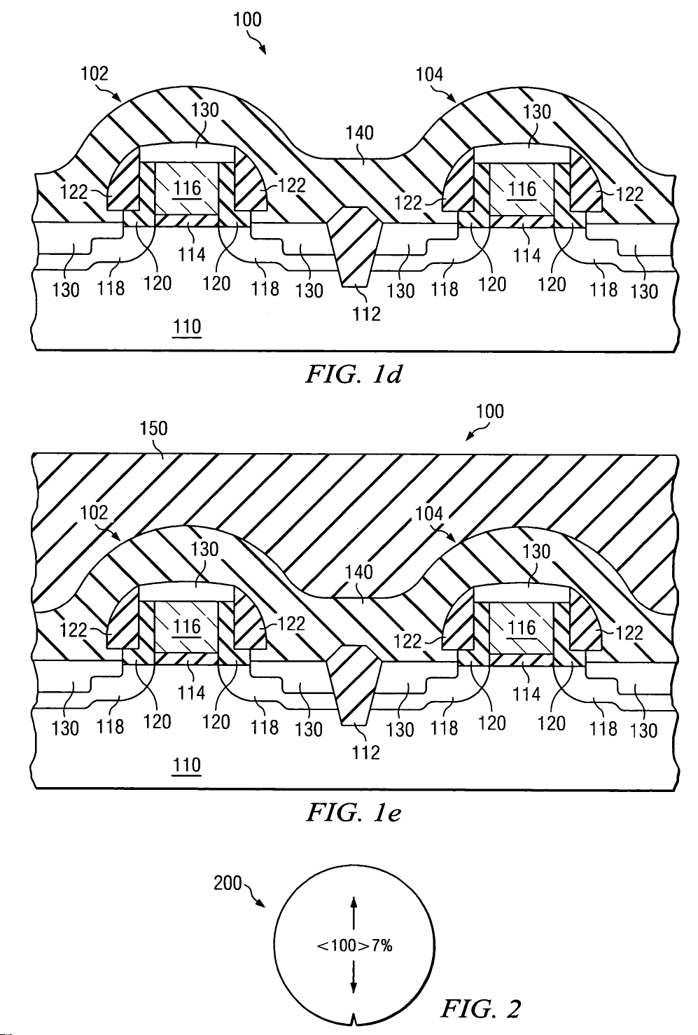

FIG. 2 illustrates a wafer 200 that may be used to fabricate semiconductor devices in accordance with one embodiment of the present invention. As discussed above, it is preferred that the current flow in the source/drain regions of the transistors 102 and 104 is substantially along the <100> direction of the silicon crystal structure. Accordingly, it is desirable to notch or otherwise mark the wafer such that the <100> direction is known. In the preferred embodiment, a 5 mm, triangular-shaped notch is placed along the edge of the wafer 200 such that the notch is located substantially along the <100> direction +/−about 7°. In alternative embodiments, other shapes, such as rectangular shapes, scratches, a flat edge, or the like, other orientations, such as perpendicular to the <100> direction or the like, and other sizes may be used.

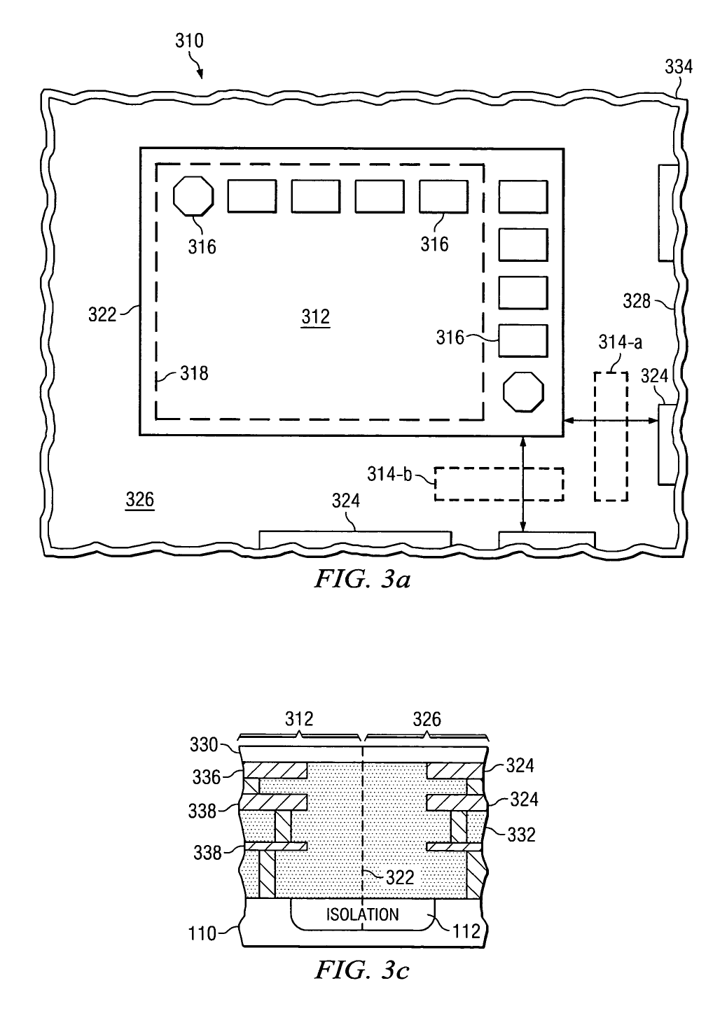

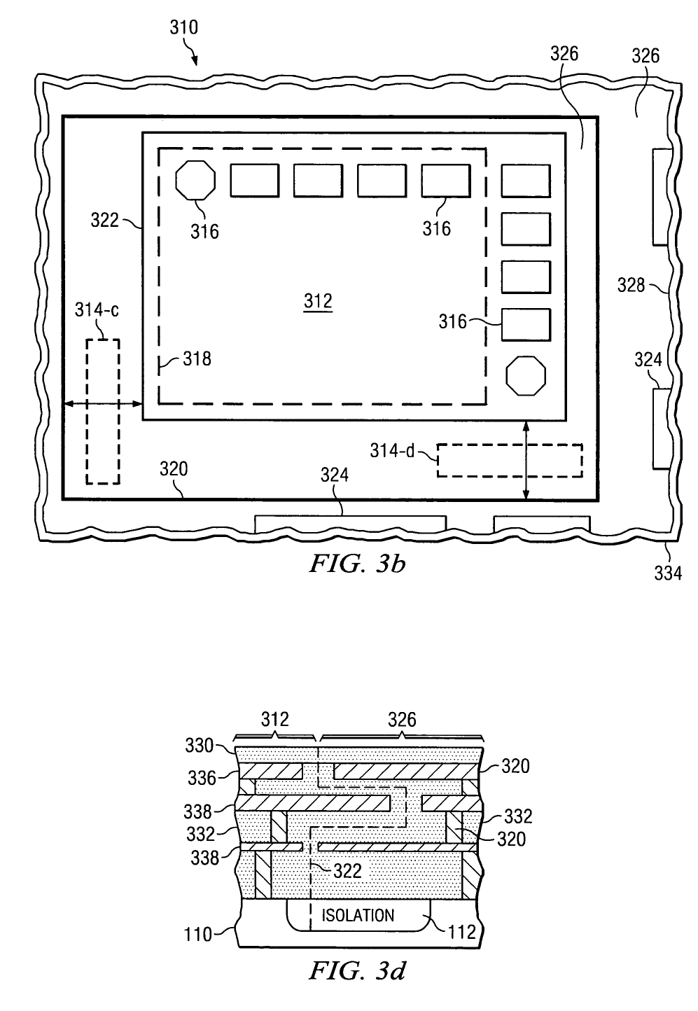

FIGS. 3a and 3b illustrate a layout or shape of semiconductor die 310 that has been sawn off from a wafer having either <100> or <110> notch orientations and may be used in accordance with embodiments of the present invention. It has been found that a wafer 200 having a silicon crystal notch orientation of <100> is more brittle while performing the wafer or die 310 sawing process, substantially along with the die-saw edge, than a wafer having a silicon crystal notch orientation of <110>, which is commonly used for fabricating semiconductor devices. In addition, it has been found that the presence of low-k dielectric may greatly deteriorate those inter-metal dielectrics 332 and/or substrate 110 chipping (or cracking) defect counts during the die 310 sawing process. The low-k materials, such as fluorine-containing or carbon-containing dielectric layers, are being commonly used for inter-metal dielectrics 332, characterized substantially with both lower dielectric constant and lower mechanical strength than conventional silicon oxide dielectric layer. Another finding of this invention is that, regardless the wafer notch orientation is <100> or <110>, the most vulnerable chipping defective locations are the neighboring strip of areas, running substantially in parallel to the die-saw edge 328 longitudinal directions, within about 300 μm to about 500 μm distance from the four die corners 334 of top view of the die 310.

As a result, it is desirable to fabricate the die 310 such that the clearance areas, preferably including 314-a, -b shown in FIGS. 3a and 314-c, -d shown in FIG. 3b, are positioned about the circumference (or the border) of each die 310. One may easily separate the area of top view of the die 310 into two neighboring regions by a border line 322 shown in FIGS. 3a, 3b, 3c and 3d, in order to realize embodiments of the present invention. The first region 312 comprises majority of microelectronics devices fabricated within die 310, such as transistors, resistors capacitors, and the like, bond pads 316 of any shapes and a plurality of metal layers (not including the redistribution metal layers of die 310 assembly or bonding process) being used as interconnects 318 for signal/power lines in the device or between the device and the outside world. A single metal layer 318 may further comprise a plurality of stacked conductive layers, such as Ti, TiN, Ta and/or TaN. The second region 326 comprises a plurality of metal layers or other microelectronics devices 324 could be used for manufacture monitoring purpose, which may or may not intend to be connected to the outside world. Meanwhile, a portion area of the second region 326 may share the same substrate space with the die-saw space for the die 310. The second region 326 in FIG. 3a further comprises a die-saw edge 328 and a clearance area 314-a, -b, the clearance area being a strip of area in the second region 326 and being positioned along the line of border 322 and about the circumference of the first region 312. The second region 326 in FIG. 3b may further comprise a metal containing seal ring 320 which may avoid mobile ions or moisture contents penetrating laterally into microelectronics devices fabricated in the first region 312 during the die 310 assembly or future operating environment conditions. A similar embodiment could be used to forming a clearance area 314-c, -d of FIG. 3b which being a strip of area in the second region 326 and being positioned substantially along the space in between the seal ring 320 and line of border 322 enclosed the first region 312. On another embodiment, the clearance area may be a strip of area in the first region 312 and could be positioned substantially along the border line 322 and about the circumference of the first region 312. Without the continuous active device area or continuous metal layers 336/338, the clearance areas 314-a, -b, -c and -d may greatly reduce those inter-metal dielectrics 332 and/or substrate 110 chipping (or cracking) defect counts during the die 310 sawing and/or assembly process.

For a device having 3 to 9 or more layers of multi-layer metal process technology, it has been found that the top metal 336 layer experiences the largest portion of stress amount resulted from the thermal/mechanical combinational effect of those materials including the substrate 110, the top protecting/passivation dielectric 330, inter-metal dielectrics 332, top metal layer 336, inter metal layers 338, the organic/inorganic assembly fillers and the molding compound over the top protecting dielectric 330. For a semiconductor manufacturing process with a fewer number of metal layers, such as less than 3 to 6 metal layers, the preferred clearance area 314 may be a strip of area with about 0.5 μm to about 10 μm in width without covering of the top metal layer or any of the inter-metal layers. In this manner, it may not only help to improve the mechanical stress induced substrate/dielectric chipping (or cracking) problems during the die-saw process, but it may also help to act as a thermal/mechanical stress buffer area to improve the potential dielectrics cracking (or delaminating) reliability problems during the die 310 assembly or packaging process. For semiconductor manufacturing process with more metal layers, such as more than 6 to 9 metal layers, then the preferable clearance area 314 may be a strip of area about 1 μm to about 20 μm in width, without sacrificing a plenty of die area, in order to cope with the getting larger thermal/mechanical stress induced by the ever thicker metal and dielectric stacked layers.

FIGS. 3c and 3d are cross-section views of the clearance area 314 illustrating examples of configurations that may be used in accordance with an embodiment of the present invention. Specifically, FIG. 3c illustrates the situation in which the clearance area, being covered and filled with dielectrics, is void of any metal layers and active areas. FIG. 3d illustrates another embodiment in which the clearance area 314 does not contain an active area and each metal layer contains a break in the clearance area. In order to get a less die assembly/package defect counts with the optimal reliability, the clearance area 314 is about 0.5 μm to about 20 μm in width and may be preferably filled with a material such as, for example, a low-k dielectrics, silicon oxide, a carbon-containing dielectric, a nitrogen-containing dielectric, a flourine-containing dielectric, or the like.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A semiconductor device comprising:
a substrate;
a transistor having a gate electrode and a source/drain region formed on the substrate such that current flow through the source/drain region is substantially along a <100> crystal orientation of the substrate;
a dielectric formed on the sides of the gate electrode and on top of the substrate adjacent to the gate electrode; and
a silicide portion formed on the surface of the substrate below the dielectric.

2. The semiconductor device of claim 1, wherein the dielectric comprises a dielectric liner and a spacer formed on the dielectric liner.

3. The semiconductor device of claim 2, wherein a ratio of a width of the spacer to a thickness of the dielectric liner is less than about 5.

4. The semiconductor device of claim 2, wherein a ratio of a width of the spacer to a length of the gate electrode is about 0.8 to about 1.5.

5. The semiconductor device of claim 2, wherein the dielectric liner comprises a plurality of dielectric liners.

6. The semiconductor device of claim 2, wherein the dielectric liner is less than about 350 Å in thickness.

7. The semiconductor device of claim 2, wherein the spacer is formed of a material selected from the group consisting essentially of silicon nitride (Si₃N₄), a nitrogen containing layer other than Si₃N₄, SiₓN_{y}, silicon oxynitride SiOₓN_{y}, silicon oxime SiOₓN_{y}:H_{z}, or a combination thereof.

8. The semiconductor device of claim 1, wherein the semiconductor device is covered with a tensile-stress film.

9. The semiconductor device of claim 8, wherein the dielectric comprises a spacer and a ratio of the thickness of the tensile-stress film to the width of the spacer is about 0.5 to about 1.6.

10. The semiconductor device of claim 8, wherein the tensile-stress film exerts a tensile stress of a magnitude of about 50 MPa to about 2 GPa.

11. The semiconductor device of claim 1, wherein the substrate comprises a wafer having a notch such that an angle formed between the <100> crystal orientation of the substrate and a line formed by the notch and the center of the wafer is less than about 7 degrees.

12. The semiconductor device of claim 1, wherein the substrate includes a shallow trench isolation imparting stress onto the substrate.

13. The semiconductor device of claim 1, wherein the substrate is bulk silicon.

14. The semiconductor device of claim 1, wherein the substrate is a semiconductor-on-insulator substrate having a an insulator layer formed on a first silicon layer, and a second silicon layer formed on the insulator layer, wherein the <110> crystal orientation of the first silicon layer is substantially aligned with the <100> crystal orientation of the second silicon layer and wherein the gate electrode is formed on the second silicon layer.

15. The semiconductor device of claim 1, wherein the substrate comprises a first semiconductor material with a first lattice constant and a second semiconductor material with a second lattice constant.

16. The semiconductor device of claim 15, wherein the first semiconductor material comprises silicon-germanium.

17. The semiconductor device of claim 1, wherein the substrate comprises a first silicon layer, a relaxed Si₁₋ₓGeₓ layer on the first silicon layer, and a strained silicon layer on the relaxed Si₁₋ₓGeₓ layer.

18. The semiconductor device of claim 17, wherein the strained silicon layer has a surface roughness of less than about 1 nm.

19. The semiconductor device of claim 17, wherein the semiconductor device includes a PMOS transistor and an NMOS transistor, a ratio of the gate width of the PMOS transistor to a gate width of the NMOS transistor is about equal to the ratio of electron mobility to hole mobility in the first silicon layer.

20. The semiconductor device of claim 17, wherein the semiconductor device includes a PMOS transistor and an NMOS transistor, a ratio of the gate width of the PMOS transistor to a gate width of the NMOS transistor is about equal to the ratio of electron mobility to hole mobility in the strained silicon layer.

21. The semiconductor device of claim 17, wherein the semiconductor device includes a PMOS transistor and an NMOS transistor, a ratio of the gate width of the PMOS transistor to the gate width of the NMOS transistor is about equal to the square root of the ratio of electron mobility to hole mobility in the first silicon layer.

22. The semiconductor device of claim 17, wherein the semiconductor device includes a PMOS transistor and an NMOS transistor, a ratio of the gate width of the PMOS transistor to the gate width of the NMOS transistor is about equal to the square root of the ratio of electron mobility to hole mobility in the strained silicon layer.

23. The semiconductor device of claim 17, wherein x is greater than about 0.1 and less than about 0.5.

24. The semiconductor device of claim 1, wherein the dielectric liner is formed of a material selected from the group consisting essentially of an oxide, a nitrogen-containing oxide, or a combination thereof.

25. The semiconductor device of claim 1, wherein the silicide portion comprises nickel silicide, cobalt silicide, platinum silicide, or palladium silicide.

26. The semiconductor device of claim 1, wherein the gate electrode comprises a gate dielectric formed of a material selected from the group consisting essentially of an oxide, a nitrogen-containing oxide, or a combination thereof.

27. The semiconductor device of claim 1, wherein the gate electrode comprises a gate dielectric having a dielectric constant greater than about 4.

28. The semiconductor device of claim 1, wherein the semiconductor device is covered by an inter-layer dielectric exerting a tensile stress substantially along the source-to-drain direction of about 0.1 GPa to about 2 GPa.

29. The semiconductor device of claim 1, wherein the semiconductor device comprises at least one of a NOR gate, a logic gate, an inverter, an XOR gate, a NAND gate, a pull-up transistor, and a pull-down transistor.

30. The semiconductor device of claim 1, further comprising a first region and a second region, the first region comprising microelectronics devices and a plurality of metal layers, the second region comprising a plurality of metal layers, and the second region further comprising a die-saw edge and a clearance area, the clearance area being an area of without a top metal layer over the substrate.

31. The semiconductor device of claim 30, wherein the clearance area in the second region comprises a strip about 0.5 μm to about 10 μm in width.

32. The semiconductor device of claim 30, wherein the clearance area in the second region comprises a strip without an inter-metal layer over the substrate.

33. The semiconductor device of claim 30, further comprising seven or more metal layers formed over the substrate.

34. The semiconductor device of claim 30, wherein the clearance area in the second region comprises a strip about 0.5 μm to about 10 μm in width without active area.

35. The semiconductor device of claim 30, wherein the clearance area in the second region comprises low-k dielectric layer with a dielectric constant less than silicon oxide.

36. The semiconductor device of claim 30, wherein the clearance area in the second region comprises a fluorine-containing low-k dielectric layer.

37. The semiconductor device of claim 30, wherein the clearance area in the second region comprises a carbon-containing low-k dielectric layer.

38. A semiconductor device comprising:
a substrate having a first semiconductor material with a first lattice constant and a second semiconductor material with a second lattice constant, and
one or more field-effect transistors formed on the second semiconductor material, wherein the current flow is substantially along the <100> crystal orientation.

39. The semiconductor device of claim 38, wherein the second semiconductor material is silicon, and the substrate is a wafer having a notch such that an angle formed between the <100> crystal orientation of the substrate and a line formed by the notch and the center of the wafer is less than about 7 degrees.

40. The semiconductor device of claim 38, wherein the first semiconductor material comprises silicon-germanium.

41. The semiconductor device of claim 38, wherein the semiconductor device includes a PMOS transistor and an NMOS transistor, a ratio of a gate width of the PMOS transistor to a gate width of the NMOS transistor is about equal to a ratio of electron mobility to hole mobility in the first semiconductor material.

42. The semiconductor device of claim 38, wherein the semiconductor device includes a PMOS transistor and an NMOS transistor, a ratio of a gate width of the PMOS transistor to a gate width of the NMOS transistor is about equal to a ratio of electron mobility to hole mobility in the second semiconductor material.

43. The semiconductor device of claim 38, wherein the semiconductor device includes a PMOS transistor and an NMOS transistor, a ratio of a gate width of the PMOS transistor to a gate width of the NMOS transistor is about equal to the square root of the ratio of electron mobility to hole mobility in first semiconductor material.

44. The semiconductor device of claim 38, wherein the semiconductor device includes a PMOS transistor and an NMOS transistor, a ratio of a gate width of the PMOS transistor to a gate width of the NMOS transistor is about equal to the square root of the ratio of electron mobility to hole mobility in the second semiconductor material.

45. The semiconductor device of claim 38, wherein the second semiconductor material has a surface roughness of less than about 1 nm.

46. The semiconductor device of claim 38, wherein the semiconductor device comprises at least one of a NOR gate, a logic gate, an inverter, and XOR gate, a NAND gate, a pull-up transistor, and a pull-down transistor.

47. The semiconductor device of claim 38, further comprising a first region and a second region, the first region comprising microelectronics devices and a plurality of metal layers, the second region comprising a plurality of metal layers, and the second region further comprising a die-saw edge and a clearance area, the clearance area being an area of without a top metal layer over the substrate.

48. The semiconductor device of claim 47, wherein the clearance area in the second region comprises a strip about 0.5 μm to about 10 μm in width.

49. The semiconductor device of claim 47, wherein the clearance area in the second region comprises a strip without an inter-metal layer over the substrate.

50. The semiconductor device of claim 47, further comprising seven or more metal layers formed over the substrate.

51. The semiconductor device of claim 47, wherein the clearance area in the second region comprises a strip about 0.5 μm to about 10 μm in width without active area.

52. The semiconductor device of claim 47, wherein the clearance area in the second region comprises low-k dielectric layer with dielectric constant less than silicon oxide.

53. The semiconductor device of claim 47, wherein the clearance area in the second region comprises a fluorine-containing low-k dielectric layer.

54. The semiconductor device of claim 47, wherein the clearance area in the second region comprises a carbon-containing low-k dielectric layer.

55. A semiconductor device comprising:
a substrate having a first silicon layer, a relaxed Si₁₋ₓGeₓ layer on the first silicon layer, and a strained silicon layer on the relaxed Si₁₋ₓGeₓ layer; and
one or more field-effect transistors formed on the strained silicon layer, wherein the current flow is along substantially the <100> crystal orientation.

56. The semiconductor device of claim 55, wherein the substrate is a wafer having a notch such that an angle formed between the <100> crystal orientation of the substrate and a line formed by the notch and the center of the wafer is less than about 7 degrees.

57. The semiconductor device of claim 55, wherein the semiconductor device includes a PMOS transistor and an NMOS transistor, a ratio of a gate width of the PMOS transistor to a gate width of the NMOS transistor is about equal to a ratio of electron mobility to hole mobility in the first silicon layer.

58. The semiconductor device of claim 55, wherein the semiconductor device includes a PMOS transistor and an NMOS transistor, a ratio of a gate width of the PMOS transistor to a gate width of the NMOS transistor is about equal to a ratio of electron mobility to hole mobility in the strained silicon layer.

59. The semiconductor device of claim 55, wherein the semiconductor device includes a PMOS transistor and an NMOS transistor, a ratio of a gate width of the PMOS transistor to a gate width of the NMOS transistor is about equal to the square root of the ratio of electron mobility to hole mobility in the first silicon layer.

60. The semiconductor device of claim 55, wherein the semiconductor device includes a PMOS transistor and an NMOS transistor, a ratio of a gate width of the PMOS transistor to a gate width of the NMOS transistor is about equal to the square root of the ratio of electron mobility to hole mobility in the strained silicon layer.

61. The semiconductor device of claim 55, wherein x is greater than about 0.1 and less than about 0.5.

62. The semiconductor device of claim 55, wherein the strained silicon layer has a surface roughness of less than about 1 nm.

63. The semiconductor device of claim 55, wherein the semiconductor device comprises at least one of a NOR gate, a logic gate, an inverter, an XOR gate, a NAND gate, a pull-up transistor, and a pull-down transistor.

64. The semiconductor device of claim 55, further comprising a first region and a second region, the first region comprising microelectronics devices and a plurality of metal layers, the second region comprising a plurality of metal layers, and the second region further comprising a die-saw edge and a clearance area, the clearance area being an area without a top metal layer over the substrate.

65. The semiconductor device of claim 64, wherein the clearance area in the second region comprises a strip about 0.5 μm to about 10 μm in width.

66. The semiconductor device of claim 64, wherein the clearance area in the second region comprises a strip without inter-metal layer over the substrate.

67. The semiconductor device of claim 64, further comprising seven or more metal layers formed over the substrate.

68. The semiconductor device of claim 64, wherein the clearance area in the second region comprises a strip about 0.5 μm to about 10 μm in width without active area.

69. The semiconductor device of claim 64, wherein the clearance area in the second region comprises a low-k dielectric layer with a dielectric constant less than silicon oxide.

70. The semiconductor device of claim 64, wherein the clearance area in the second region comprises a fluorine-containing low-k dielectric layer.

71. The semiconductor device of claim 64, wherein the clearance area in the second region comprises a carbon-containing low-k dielectric layer.

72. A semiconductor device comprising:
a substrate;
a first transistor formed on the substrate, the first transistor having a first gate electrode and a first source/drain region, the first transistor being oriented such that current flow through the first source/drain region is substantially along the <100> crystal orientation of the substrate; and
a second transistor formed on the substrate, the second transistor having a second gate electrode and a second source/drain region, the second transistor being oriented such that current flow through the second source/drain region is substantially along the <100> crystal orientation of the substrate;
wherein each of the first gate electrode and the second gate electrode have spacers formed alongside, the spacers of the first transistor being larger than the spacers of the second transistors.

73. The semiconductor device of claim 72, wherein at least one of the first transistor and the second transistor have spacers formed above a silicide region of the substrate.

74. The semiconductor device of claim 72, wherein the substrate comprises a wafer having a notch such that an angle formed between the <100> crystal orientation of the substrate and a line formed by the notch and the center of the wafer is less than about 7 degrees.

75. The semiconductor device of claim 72, wherein the first transistor is a PMOS transistor and the second transistor is an NMOS transistor, and the second transistor has spacers formed above a silicided region of the substrate.

76. The semiconductor device of claim 72, wherein the substrate includes a shallow trench isolation imparting stress onto the substrate.

77. The semiconductor device of claim 72, wherein the substrate is bulk silicon.

78. The semiconductor device of claim 72, wherein the substrate is a semiconductor-on-insulator substrate having an insulator layer formed on a first silicon layer and a second silicon layer formed on the insulator layer and wherein the substrate comprises a wafer having a notch such that an angle formed between the <100> crystal orientation of the second silicon layer and a line formed by the notch and the center of the wafer is less than about 7 degrees.

79. The semiconductor device of claim 72, wherein the substrate comprises a first semiconductor material with a first lattice constant and a second semiconductor material with a second lattice constant.

80. The semiconductor device of claim 79, wherein the first semiconductor material comprises silicon-germanium.

81. The semiconductor device of claim 72, wherein the substrate comprises a first silicon layer, a relaxed Si₁₋ₓGeₓ layer on the first silicon layer, and a strained silicon layer on the relaxed Si₁₋ₓGeₓ layer.

82. The semiconductor device of claim 81, wherein the strained silicon layer has a surface roughness of less than about 1 nm.

83. The semiconductor device of claim 81, wherein the semiconductor device includes a PMOS transistor and an NMOS transistor, a ratio of a gate width of the PMOS transistor to a gate width of the NMOS transistor is about equal to a ratio of electron mobility to hole mobility in the first silicon layer.

84. The semiconductor device of claim 81, wherein the semiconductor device includes a PMOS transistor and an NMOS transistor, a ratio of a gate width of the PMOS transistor to a gate width of the NMOS transistor is about equal to a ratio of electron mobility to hole mobility in the strained silicon layer.

85. The semiconductor device of claim 81, wherein the semiconductor device includes a PMOS transistor and an NMOS transistor, a ratio of a gate width of the PMOS transistor to a gate width of the NMOS transistor is about equal to the square root of the ratio of electron mobility to hole mobility in the first silicon layer.

86. The semiconductor device of claim 81, wherein the semiconductor device includes a PMOS transistor and an NMOS transistor, a ratio of a gate width of the PMOS transistor to a gate width of the NMOS transistor is about equal to the square root of the ratio of electron mobility to hole mobility in the strained silicon layer.

87. The semiconductor device of claim 81, wherein x is greater than about 0.1 and less than about 0.5.

88. The semiconductor device of claim 72, wherein at least one of the first transistor and the second transistor have a dielectric liner between the spacer and the substrate, the dielectric liner being formed of a material selected from the group consisting essentially of an oxide, a nitrogen-containing oxide, or a combination thereof.

89. The semiconductor device of claim 88, wherein a ratio of a width of the spacer to a thickness of the dielectric liner is less than about 5.

90. The semiconductor device of claim 88, wherein the dielectric liner is less than about 350 Å in thickness.

91. The semiconductor device of claim 72, wherein the silicided region comprises nickel silicide, cobalt silicide, platinum silicide, or palladium silicide.

92. The semiconductor device of claim 72, wherein at least one of the first transistor and the second transistor is covered with a tensile-stress film.

93. The semiconductor device of claim 92, wherein the tensile-stress film exerts a tensile stress of a magnitude of about 50 MPa to about 2 GPa.

94. The semiconductor device of claim 71, wherein the spacers are formed of a material selected from the group consisting of silicon nitride (Si₃N₄), a nitrogen containing layer other than Si₃N₄, SiₓN_{y}, silicon oxynitride SiOₓN_{y}, silicon oxime SiOₓN_{y}:H_{z}, and a combination thereof.

95. The semiconductor device of claim 71, wherein an inter-layer dielectric is deposited over the first transistor and the second transistor, the inter-layer dielectric exerting a tensile stress substantially along the source-to-drain direction of about 0.1 GPa to about 2 GPa.

96. A method of forming a semiconductor device, the method comprising:
providing a substrate;
forming a transistor on the substrate, the transistor having a gate electrode and spacers formed alongside the gate electrode; and
forming a silicided region along the surface of the substrate such that at least a portion of the silicided region extends beneath the spacers,
wherein current flow through a source/drain region of the transistor is substantially along a <100> crystal orientation of the substrate.

97. The method of claim 96, further comprising forming a shallow trench isolation imparting stress onto the substrate.

98. The method of claim 96, wherein the substrate is bulk silicon.

99. The method of claim 96, wherein the substrate is a semiconductor-on-insulator having an insulator layer formed on a first silicon layer and a second silicon layer formed on the insulator layer, wherein a <110> crystal orientation of the first silicon layer is substantially aligned with a <100> crystal orientation of the second silicon layer.

100. The method of claim 99, wherein the second silicon layer has a surface roughness of less than about 1 nm.

101. The method of claim 96, wherein the substrate comprises a first semiconductor material with a first lattice constant and a second semiconductor material with a second lattice constant.

102. The method of claim 101, wherein the first semiconductor material is SiGe.

103. The method of claim 96, wherein the substrate comprises a first silicon layer, a relaxed Si₁₋ₓGeₓ layer on the first silicon layer, and a strained silicon layer on the relaxed Si₁₋ₓGeₓ layer.

104. The method of claim 103, wherein the semiconductor device includes a PMOS transistor and an NMOS transistor, a ratio of a gate width of the PMOS transistor to a gate width of the NMOS transistor is about equal to the ratio of electron mobility to hole mobility in the first silicon layer.

105. The method of claim 103, wherein the semiconductor device includes a PMOS transistor and an NMOS transistor, a ratio of a gate width of the PMOS transistor to a gate width of the NMOS transistor is about equal to a ratio of electron mobility to hole mobility in the strained silicon layer.

106. The method of claim 103, wherein the semiconductor device includes a PMOS transistor and an NMOS transistor, a ratio of a gate width of the PMOS transistor to a gate width of the NMOS transistor is about equal to the square root of a ratio of electron mobility to hole mobility in the first silicon layer.

107. The method of claim 103, wherein the semiconductor device includes a PMOS transistor and an NMOS transistor, a ratio of a gate width of the PMOS transistor to a gate width of the NMOS transistor is about equal to the square root of a ratio of electron mobility to hole mobility in the strained silicon layer.

108. The method of claim 103, wherein x is greater than about 0.1 and less than about 0.5.

109. The method of claim 96, wherein forming the transistor includes forming a dielectric liner between the spacers and the substrate, the dielectric liner being formed of a material selected from the group consisting of an oxide, a nitrogen-containing oxide, or a combination thereof.

110. The method of claim 109, wherein a ratio of a width of the spacer to a thickness of the dielectric liner is less than about 5.

111. The method of claim 109, wherein the dielectric liner is less than about 350 Å in thickness.

112. The method of claim 96, wherein a ratio of a width of the spacer to a length of the gate electrode is about 0.8 to about 1.5.

113. The method of claim 96, wherein the silicided region comprises nickel silicide, cobalt silicide, platinum silicide, or palladium silicide.

114. The method of claim 96, further comprising forming a tensile-stress film over the transistor.

115. The method of claim 114, wherein a ratio of the thickness of the tensile-stress film to the width of the spacer is about 0.5 to about 1.6.

116. The method of claim 114, wherein the tensile-stress film exerts a tensile stress of a magnitude of about 50 MPa to about 2 GPa.

117. The method of claim 96, wherein the spacers are formed of a material selected from the group consisting essentially of silicon nitride (Si₃N₄), or a nitrogen containing layer other than Si₃N₄, SiₓN_{y}, silicon oxynitride SiOₓN_{y}, silicon oxime SiOₓN_{y}:H_{z}, and a combination thereof.

118. The method of claim 96, further comprising forming an inter-layer dielectric over the transistor, the inter-layer dielectric exerting a tensile stress substantially along the source-to-drain direction of about 0.1 GPa to about 2 GPa.

119. The method of claim 96, wherein the step of forming a silicided region includes:
etching a recess region in a dielectric liner, the dielectric liner being positioned between the spacer and the substrate;
pre-cleaning the substrate; and
forming the silicided region.

120. The method of claim 119, wherein the step of pre-cleaning is performed by wet dipping the substrate in a solution of hydrofluoric acid, sulphuric acid, hydrogen peroxide, NH₄OH, or a combination thereof.

121. The method of claim 96, wherein the silicide formed below the spacer is formed less than about 70% of the width of the spacer.

122. The method of claim 96, further comprising forming microelectronics devices and a plurality of metal layers in a first region and forming a plurality of metal layers in a second region such that the second region comprises a die-saw edge and a clearance area, the clearance area being an area of without a top metal layer over the substrate.

123. The method of claim 122, wherein the clearance area in the second region comprises a strip about 0.5 μm to about 10 μm in width.

124. The method of claim 122, wherein the clearance area in the second region comprises a strip without inter metal layer over the substrate.

125. The method of claim 122, wherein the plurality of layers includes seven or more metal layers formed over the substrate.

126. The method of claim 122, wherein the clearance area in the second region a strip about 0.5 μm to about 10 μm in width without active area.

127. The method of claim 122, wherein the clearance area in the second region comprises a low-k dielectric layer with dielectric constant less than silicon oxide.

128. The method of claim 122, wherein the clearance area in the second region comprises a fluorine-containing low-k dielectric layer.

129. The method of claim 122, wherein the clearance area in the second region comprises a carbon-containing low-k dielectric layer.

130. A method of forming a semiconductor device, the method comprising:
providing a substrate;
forming a first transistor on the substrate such that current flow through a source/drain region of the first transistor is substantially along a <100> crystal orientation of the substrate, the first transistor having a first gate electrode and a first spacer formed alongside the first gate electrode; and
forming a second transistor on the substrate such that current flow through a source/drain region of the second transistor is substantially along a <100> crystal orientation of the substrate, the second transistor having a second gate electrode and a second spacer formed alongside of a second gate electrode, the second spacer being smaller than the first spacer.

131. The method of claim 130, wherein a silicide region is formed substantially along the surface of the source/drain region such that at least a portion of the silicide region extends beneath at least one of the first spacer and the second spacer.

132. The method of claim 130, wherein the first transistor is a PMOS transistor formed in an n-well and the second transistor is an NMOS transistor formed in a p-well.

133. The method of claim 130, further comprising the step of forming a shallow trench isolation imparting stress onto the substrate.

134. The method of claim 130, wherein the substrate is bulk silicon.

135. The method of claim 130, wherein the substrate is a semiconductor-on-insulator having an insulator layer formed on a first silicon layer and a second silicon layer formed on the insulator layer, wherein a <110> crystal orientation of the first silicon layer is substantially aligned with a <100> crystal orientation of the second silicon layer.

136. The method of claim 130, wherein the substrate comprises a first semiconductor material with a first lattice constant and a second semiconductor material with a second lattice constant.

137. The method of claim 136, wherein the first semiconductor material is SiGe.

138. The method of claim 130, wherein the substrate comprises a first silicon layer, a relaxed Si₁₋ₓGeₓ layer on the first silicon layer, and a strained silicon layer on the relaxed Si₁₋ₓGeₓ layer.

139. The method of claim 138, wherein the strained silicon layer has a surface roughness of less than about 1 nm.

140. The method of claim 138, wherein the semiconductor device includes a PMOS transistor and an NMOS transistor, a ratio of a gate width of the PMOS transistor to a gate width of the NMOS transistor is about equal to a ratio of electron mobility to hole mobility in the first silicon layer.

141. The method of claim 138, wherein the semiconductor device includes a PMOS transistor and an NMOS transistor, a ratio of a gate width of the PMOS transistor to a gate width of the NMOS transistor is about equal to a ratio of electron mobility to hole mobility in the strained silicon layer.

142. The method of claim 138, wherein the semiconductor device includes a PMOS transistor and an NMOS transistor, a ratio of a gate width of the PMOS transistor to a gate width of the NMOS transistor is about equal to the square root of a ratio of electron mobility to hole mobility in the first silicon layer.

143. The method of claim 138, wherein the semiconductor device includes a PMOS transistor and an NMOS transistor, a ratio of a gate width of the PMOS transistor to a gate width of the NMOS transistor is about equal to the square root of a ratio of electron mobility to hole mobility in the strained silicon layer.

144. The method of claim 138, wherein x is greater than about 0.1 and less than about 0.5.

145. The method of claim 130, wherein the step of forming the second transistor includes forming a dielectric liner between the second spacer and the substrate, the dielectric liner being formed of a material selected from the group consisting of an oxide, a nitrogen-containing oxide, or a combination thereof.

146. The method of claim 145, wherein a ratio of a width of the second spacer to a thickness of the dielectric liner is less than about 5.

147. The method of claim 145, wherein the dielectric liner is less than about 350 Å in thickness.

148. The method of claim 130, wherein the silicided region comprises nickel silicide, cobalt silicide, platinum silicide, or palladium silicide.

149. The method of claim 130, further comprising the step of forming a tensile-stress film over the first and second transistor.

150. The method of claim 149, wherein a ratio of the thickness of the tensile-stress film to the width of the spacer is about 0.5 to about 1.6.

151. The method of claim 149, wherein the tensile-stress film exerts a tensile stress of a magnitude of about 50 MPa to about 2 GPa.

152. The method of claim 130, wherein the spacers are formed of a material selected from the group consisting of silicon nitride (Si₃N₄), or a nitrogen containing layer other than Si₃N₄, SiₓN_{y}, silicon oxynitride SiOₓN_{y}, silicon oxime SiOₓN_{y}:H_{z}, and a combination thereof.

153. The method of claim 130, further comprising the step of forming an inter-layer dielectric over the first and second transistor, the inter-layer dielectric exerting a tensile stress along substantially the source-to-drain direction of about 0.1 GPa to 2 GPa.

154. The method of claim 130, wherein the step of forming a silicided region includes:
etching a recess region in a dielectric liner, the dielectric liner being positioned between the spacer and the substrate;
pre-cleaning the substrate; and
forming the silicided region.

155. The method of claim 154, wherein the step of pre-cleaning is performed by wet dipping the substrate in a solution of hydrofluoric acid, sulphuric acid, hydrogen peroxide, NH₄OH, or a combination thereof.

156. The method of claim 130, wherein the silicided region formed below the spacer is formed less than about 70% of the width of the spacer.

157. The method of claim 130, further comprising forming microelectronics devices and a plurality of metal layers in a first region and a plurality of metal layers in a second region such that the second region comprises a die-saw edge and a clearance area, the clearance area being an area without a top metal layer over the substrate.

158. The method of claim 157, wherein the clearance area in the second region comprises a strip about 0.5 μm to about 10 μm in width.

159. The method of claim 157, wherein the clearance area in the second region comprises a strip without inter metal layer over the substrate.

160. The method of claim 157, wherein the plurality of metal layers comprises seven or more metal layers formed over the substrate.

161. The method of claim 157, wherein the clearance area in the second region comprises a strip about 0.5 μm to about 10 μm in width without active area.

162. The method of claim 157, wherein the clearance area in the second region comprises a low-k dielectric layer with a dielectric constant less than silicon oxide.

163. The method of claim 157, wherein the clearance area in the second region comprises a fluorine-containing low-k dielectric layer.

164. The method of claim 157, wherein the clearance area in the second region comprises a carbon-containing low-k dielectric layer.

165. A semiconductor device comprising:
a substrate;
a transistor having a gate electrode and a source/drain region formed on the substrate:
a low-K dielectric formed over the substrate and the gate electrode; and a silicide portion formed on the surface of the substrate below the dielectric;
wherein the semiconductor device includes a first region and a second region, the first region comprising microelectronics devices and a plurality of metal layers, the second region comprising at least one metal layer, and the second region further comprising a die-saw edge and a clearance area, the clearance area being an area of without a top metal layer over the substrate.

166. The semiconductor device of claim 165, wherein the clearance area in the second region comprises a strip 0.5 μm to about 10 μm in width.

167. The semiconductor device of claim 165, wherein the clearance area in the second region comprises a strip without inter metal layer over the substrate.

168. The semiconductor device of claim 165, wherein the clearance area in the second region comprises a strip about 0.5 μm to about 10 μm in width without active area.

169. The semiconductor device of claim 165, wherein the clearance area in the second region comprises a low-k dielectric layer with dielectric constant less than silicon oxide.

170. The semiconductor device of claim 164, wherein the plurality of metal layers comprises more than 7 metal layers in the first region over the substrate, and the clearance area in the second region comprises a fluorine-containing low-k dielectric layer.

171. The semiconductor device of claim 164, wherein the plurality of metal layers comprises more than 8 metal layers in the first region over the substrate, and the clearance area in the second region comprises a fluorine-containing low-k dielectric layer.

172. The semiconductor device of claim 164, wherein the plurality of metal layers comprises more than 5 metal layers in the first region over the substrate, the clearance area in the second region comprises a carbon-containing low-k dielectric layer.

173. The semiconductor device of claim 164, wherein the plurality of metal layers comprises more than 6 metal layers in the first region over the substrate, the clearance area in the second region comprises a carbon-containing low-k dielectric layer.

174. The semiconductor device of claim 164, wherein the clearance area is positioned substantially in parallel to the die-saw edge longitudinal direction, within about 300 μm distance from the die corner.
